(19) United States
(12) Patent Application Publication
(10) Pub. No.: US 2018/0128873 A1
(43) Pub. Date: May 10, 2018

(54) MULTI-NODE TESTING SYSTEM AND METHOD

(71) Applicant: Xcerra Corporation, Norwood, MA (US)

(72) Inventors: TODOR K. PETROV, Mansfield, MA (US); RICHARD LIGGIERO, Tewksbury, MA (US)

(21) Appl. No.: 15/804,262

(22) Filed: Nov. 6, 2017

Related U.S. Application Data
(60) Provisional application No. 62/419,068, filed on Nov. 8, 2016.

(51) Int. Cl. G01R 31/28; G01R 1/073

(52) U.S. Cl. CPC G01R 31/2834; G01R 1/07378

(57) ABSTRACT

An automated microtester, for simultaneously testing a plurality of devices under test, includes a processing system including a plurality of processor assemblies. A plurality of test sites are configured to releasably engage a plurality of devices under test. An instrumentation system is controllable by the processing system and is configured to provide one or more input signals to the plurality of test sites and read one or more monitored signals from the plurality of test sites.

### RELATED APPLICATION

This application claims the benefit of U.S. Provisional Application No. 62/419,068, filed on 8 Nov. 2016 and entitled “HIGH-THROUGHPUT MULTI-NODE TEST SYSTEM”.

### TECHNICAL FIELD

This disclosure relates to automated testing systems and, more particularly, to high-throughput, multi-node, automated testing systems.

### BACKGROUND

Automated test equipment systems may be used to test various electronic components, which are often referred to as devices under test (DUTs). Such systems may automate the testing of such components, wherein a component may be subjected to a battery of different tests in some form of logical fashion. Additionally, such systems may provide further levels of automation, wherein the components being tested may be automatically swapped out (upon completion of a testing procedure) and replaced with a component that has yet to be tested.

Due to the high quantity of devices being tested, automated test equipment systems may be configured to test multiple devices in parallel. Unfortunately, such systems tend to be inefficient. Specifically, these automated test equipment systems may simultaneously connect to multiple DUTs so that they may simultaneously execute test programs concurrently. Unfortunately, due to bus restrictions, shared resources, and threading limitations of the central computer, the testing of the individual DUTs is not entirely parallel (thus resulting in the above-mentioned inefficiencies).

### SUMMARY OF DISCLOSURE

Automated Microtester

In one implementation, an automated microtester, for simultaneously testing a plurality of devices under test, includes a processing system including a plurality of processor assemblies. A plurality of test sites are configured to releasably engage a plurality of devices under test. An instrumentation system is controllable by the processing system and is configured to provide one or more input signals to the plurality of test sites and read one or more monitored signals from the plurality of test sites.

One or more of the following features may be included. The processing system may include a multicore processor. The plurality of processor assemblies included within the processing system may include a plurality of processor cores included within the multicore processor. The plurality of test sites may be configured to receive a plurality of adapter boards. The plurality of adapter boards may be configured to releasably receive the plurality of devices under test. Each of the plurality of adapter boards may be configured to releasably receive a single device under test. Each of the plurality of adapter boards may be configured to releasably receive a plurality of devices under test. The processing system may be configured to execute an automated test process. The automated test process may be configured to control the instrumentation system and define the one or more input signals provided to the plurality of test sites and the one or more monitored signals read from the plurality of test sites. The automated test process may be configured to simultaneously test each of the plurality of devices under test. A DUT swap system may be configured to releasably couple the plurality of devices under test to the plurality of test sites prior to testing the devices under test. The DUT swap system may be further configured to uncouple the plurality of devices under test from the plurality of test sites after testing the devices under test.

In another implementation, an automated microtester, for simultaneously testing a plurality of devices under test, includes a processing system including a plurality of processor cores. A plurality of test sites are configured to releasably engage a plurality of devices under test. An instrumentation system is controllable by the processing system and is configured to provide one or more input signals to the plurality of test sites and read one or more monitored signals from the plurality of test sites.

One or more of the following features may be included. The processing system may include a multicore processor. The plurality of test sites may be configured to receive a plurality of adapter boards. The plurality of adapter boards may be configured to releasably receive the plurality of devices under test.

In another implementation, an automated microtester, for simultaneously testing a plurality of devices under test, includes a multicore processor including a plurality of processor cores. A plurality of test sites are configured to releasably engage a plurality of devices under test. An instrumentation system is controllable by the processing system and is configured to provide one or more input signals to the plurality of test sites and read one or more monitored signals from the plurality of test sites. The plurality of test sites are configured to receive a plurality of adapter boards and the plurality of adapter boards are configured to releasably receive the plurality of devices under test.

One or more of the following features may be included. The multicore processor may be configured to execute an automated test process. The automated test process may be configured to simultaneously test each of the plurality of devices under test

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a diagrammatic view of an automated microtester, including a processing system, according to one implementation of this disclosure;

FIG. 2 is a diagrammatic view of an automated microtester array, including a plurality of automated microtesters, according to one implementation of this disclosure; and

FIG. 3 is a flowchart of an automated array process executed by the automated microtester array of FIG. 2.

Like reference symbols in the various drawings indicate like elements.

### DETAILED DESCRIPTION OF THE PREFERRED EMBODIMENTS

### System Overview:

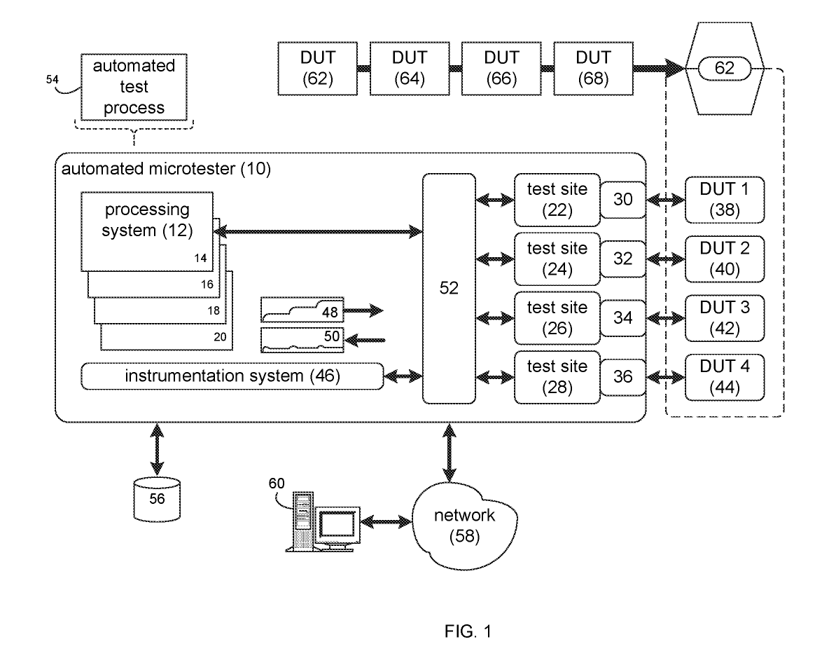

Referring to FIG. 1, there is shown automated microtester 10. Examples of automated microtester 10 may include, but are not limited to, systems that automate the verification and validation of devices under test (DUTs). Automated test equipment systems (e.g. automated microtester 10) may be used to test various electronic components in an automated fashion. Typically, the devices under test may be subjected to a battery of different tests, wherein the testing procedures may be automated in a logical fashion. For example, during the testing of a power supply, the power supply may be subjected to varying voltage levels and varying voltage frequencies. Further, during the testing of a noise canceling circuit, such a circuit may be subjected to varying levels and frequencies of noise to confirm the satisfactory performance of the same.

Automated microtester 10 may include processing system 12. Examples of processing system 12 may include but is not limited to a multi-core processor that includes a plurality of processing assemblies (e.g., processing cores 14, 16, 18, 20). Alternatively, processing system 12 may include a plurality of discrete microprocessors. While the following discussion concerns processing system 12 including four processing cores (e.g., processing cores 14, 16, 18, 20), this is for illustrative purposes only and is not intended to be a limitation of this disclosure, as other configurations are possible and are considered to be within the scope of this disclosure. For example, the number of processing cores included within processing system 12 may be increased or decreased depending upon the level of computational power required by automated microtester 10.

Automated microtester 10 may include one or more test sites (e.g. test site 22, 24, 26, 28) configured to releasably receive at least one device under test. Automated microtester 10 may be configured to include one test site (e.g. test site 22, 24, 26, 28) for each processing core (e.g., processing core 14, 16, 18, 20) included within processing system 12.

Automated microtester 10 may be configured to work with one or more adapter boards (e.g., adapter boards 30, 32, 34, 36), wherein the adapter boards (e.g., adapter boards 30, 32, 34, 36) may be configured to adapt the test sites (e.g. test sites 22, 24, 26, 28) to the particular type of device under test (e.g., devices under test 38, 40, 42, 44). For example, the test sites (e.g. test sites 22, 24, 26, 28) may be a universal connector assembly that may be configured to provide signals to and/or read signals from the devices under test (e.g., devices under test 38, 40, 42, 44).

While the following discussion concerns a single test site (and device under test) being associated with a single processing core (e.g., test site 22/device under test 38 being associated with processing core 14; test site 24/device under test 40 being associated with processing core 16; test site 26/device under test 42 being associated with processing core 18; and test site 28/device under test 44 being associated with processing core 20); this is for illustrative purposes only and is not intended to be a limitation of this disclosure, as other configurations are possible. For example, one or more of the adapter boards (e.g., adapter boards 30, 32, 34, 36) may be configured to adapt a single test site (e.g. test site 22, 24, 26, 28) to multiple devices under test, thus enabling (in this example) four processing cores (e.g., cores 14, 16, 18, 20) to be associated with e.g., eight (with 2× adapter boards), twelve (with 3× adapter boards) or more devices under test.

Alternatively, the test sites (e.g. test site 22, 24, 26, 28) may be configured to work without adapter boards (e.g., adapter boards 30, 32, 34, 36), wherein the test sites (e.g. test site 22, 24, 26, 28) may be configured to allow devices under test (e.g., devices under test 38, 40, 42, 44) to directly plug into/couple with the test sites (e.g. test site 22, 24, 26, 28).

Automated microtester 10 may include instrumentation system 46. As discussed above, input signals (e.g., input signal 48), examples of which may include but are not limited to various voltage signals and current signals, may be provided to the devices under test (e.g., devices under test 38, 40, 42, 44) via (in this example) test sites 22, 24, 26, 28. Additionally, monitored signals (e.g., monitored signal 50), examples of which may include but are not limited to voltage signals and current signals, may be read from the various devices under test (e.g., devices under test 38, 40, 42, 44) via (in this example) test sites 22, 24, 26, 28. Accordingly, instrumentation system 46 may be configured to provide the above-referenced input signals (e.g., input signal 48) to the devices under test (e.g., devices under test 38, 40, 42, 44) and may be configured to read the above-referenced monitored signals (e.g., monitored signals 50) from the devices under test (e.g., devices under test 38, 40, 42, 44) during any testing procedures/operations.

Processing system 12 (including processing cores 14, 16, 18, 20) and test sites 22, 24, 26, 28 may be coupled together via interconnection platform 52 (e.g., a PCIe bus or a USB bus).

If configured as a PCIe bus, interconnection platform 52 may allow for test sites 22, 24, 26, 28 and processing system 12 (including processing cores 14, 16, 18, 20) to communicate via interconnection platform 52 using the PCIe communication standards. As is known in the art, PCIe (Peripheral Component Interconnect Express) is a high-speed serial computer expansion bus standard designed to replace older bus systems (e.g., PCI, PCI-X, and AGP). Through the use of PCIe, higher maximum system bus throughput may be achieved. Other benefits may include lower I/O pin count, a smaller physical footprint, better performance-scaling for bus devices, a more detailed error detection and reporting mechanism, and native plug-n-play functionality.

If configured as a USB bus, interconnection platform 52 may allow for test sites 22, 24, 26, 28 and processing system 12 (including processing cores 14, 16, 18, 20) to communicate via interconnection platform 52 using the USB communication standards. As is known in the art, Universal Serial Bus (USB) is an industry standard that defines the cables, connectors and communications protocols used in a bus for connection, communication, and power supply between computers and various electronic devices/components.

Automated microtester 10 may execute one or more operating systems, examples of which may include but are not limited to: Microsoft Windows™; Linux, Unix, or a custom operating system.

Automated microtester 10 may execute one or more automated test programs (e.g. automated test process 54), wherein automated test process 54 may be configured to automate the testing of various devices under test (e.g., devices under test 38, 40, 42, 44). Through the use of automated test process 54, an administrator (not shown) of automated microtester 10 may define and execute testing procedures/routines for the various devices under test (e.g., devices under test 38, 40, 42, 44) that e.g., provide input signals (e.g., input signal 48) to and read monitored signals (e.g., monitored signal 50) from e.g., devices under test 38, 40, 42, 44. The various devices under test (e.g., devices under test 38, 40, 42, 44) may all be the same type of device or may be different types of devices. For example, devices under test 38, 40, 42, 44 may include a plurality of device types, wherein e.g., a first automated test process may be executed on the processing cores associated with the first type of device, while a second automated test process may be executed on processing cores associated with the second type of device.

The instruction sets and subroutines of automated test process 54, which may be stored on storage device 56 coupled to/included within automated microtester 10, may be executed by one or more processors (e.g., processing system 12, including processing cores 14, 16, 18, 20) and one or more memory architectures (not shown) included within automated microtester 10. Examples of storage device 56 may include but is not limited to: a hard disk drive; a random access memory (RAM); a read-only memory (ROM); and all forms of flash memory storage devices.

Processing system 12 may be connected to one or more networks (e.g., network 58), examples of which may include but are not limited to: a USB hub, an Ethernet network (e.g., a local area network or a wide area network), an intranet or the internet. Accordingly, automated microtester 10 may be administered and/or controlled via network 58. Therefore, an administrator (not shown) may use a remote computing device (e.g., remote computing device 60) coupled to network 58 to define and/or administer various testing procedures and/or routines via automated test process 54. Examples of remote computing device 60 may include but are not limited to a personal computer, a notebook computer, a tablet computer and a smartphone.

Automated microtester 10 may include automated DUT swap system 62 that may be configured to uncouple the devices under test (e.g., devices under test 38, 40, 42, 44) from automated microtester 10 and couple new devices under test (e.g., devices under test 62, 64, 66, 68) to automated microtester 10. An example of automated DUT swap system 62 may include but is not limited to one or more robotic arms (or similar devices) that may be configured to remove devices under test (e.g., devices under test 38, 40, 42, 44) from automated microtester 10 upon e.g., the completion of automated test process 54 and may couple the new devices under test (e.g., devices under test 62, 64, 66, 68) to automated microtester 10 so that e.g., automated test process 54 may be performed on the new devices under test (e.g., devices under test 62, 64, 66, 68). This swapping and testing procedure may be repeated until all of the devices under test that need to be tested have been tested.

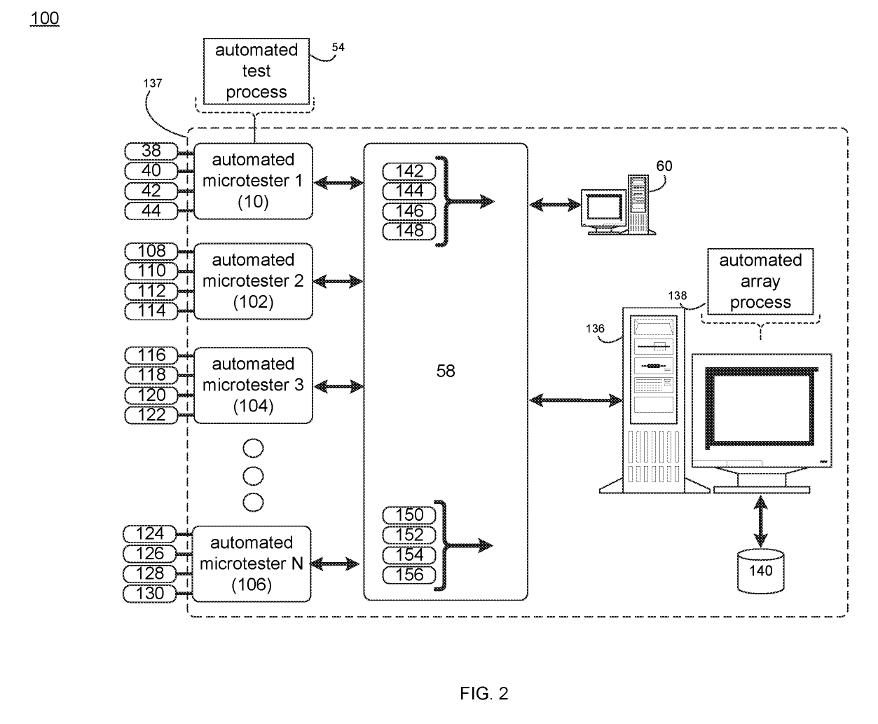

Referring also to FIG. 2, there is shown automated microtester array 100, wherein automated microtester array may be configured to simultaneously test multiple devices under test. For example, automated microtester array 100 may be configured to include a plurality of automated microtesters (e.g., automated microtester 10, automated microtester 102, automated microtester 104 and automated microtester 106). While in this particular example, automated microtester array 100 is shown to include four automated microtesters (as represented by automated microtester 1, automated microtester 2, automated microtester 3 and automated microtester N), this is for illustrative purposes only and is not intended to be a limitation of this disclosure as other configurations are possible. For example, the quantity of automated microtesters included within automated microtester array 100 may be increased or decreased depending upon the design criteria and needs of automated microtester array 100. Specifically and through such a configuration, automated microtester array 100 may be scaled limitlessly up to the capability of the network (e.g., network 58) that is coupling the various components of automated microtester array 100, thus allowing automated microtester array 100 to achieve near perfect parallelism (˜100% parallel test efficiency).

In the manner described above, each of automated microtesters 10, 102, 104, 106 may be configured to simultaneously test a plurality of devices under test. For example and as discussed above, automated microtester 10 may be configured to simultaneously test four devices under test (namely devices under test 38, 40, 42, 44). Further, automated microtester 102 may be configured to simultaneously test four devices under test (namely devices under test 108, 110, 112, 114; automated microtester 104 may be configured to simultaneously test four devices under test (namely devices under test 116, 118, 120, 122); and automated microtester 106 may be configured to simultaneously test four devices under test (namely devices under test 124, 126, 128, 130); thus allowing in this exemplary implementation of automated microtester array 100 the simultaneous testing of sixteen devices under test. And since the quantity of automated microtesters included within automated microtester array 100 may be increased or decreased depending upon the design criteria and needs of automated microtester array 100, the quantity of devices under test that may be simultaneously tested by automated microtester array 100 may also be increased or decreased depending upon the design criteria and needs of automated microtester array 100.

Automated microtester array 100 may include central computing system 136. Examples of central computing system 136 may include but are not limited to a personal computer, a server computer, a series of server computers, a mini computer or a single-board computer. Central computing system 136 may execute one or more operating systems, examples of which may include but are not limited to: Microsoft Windows™; Linux, Unix, or a custom operating system. The plurality of automated microtesters (e.g., automated microtester 10, automated microtester 102, automated microtester 104 and automated microtester 106) and central computing system 136 included within automated microtester array 100 may all be separate and distinct components that are interconnected via network 58. Additionally/alternatively, the plurality of automated microtesters (e.g., automated microtester 10, automated microtester 102, automated microtester 104 and automated microtester 106) and central computing system 136 included within automated microtester array 100 may all be incorporated into a common enclosure (e.g., common enclosure 137), wherein network 58 is included within common enclosure 137.

Central computing system 136 (within automated microtester array 100) may execute one or more automated array programs (e.g. automated array process 138), wherein automated array process 138 may be configured to automate the testing of various devices under test (e.g., devices under test 38, 40, 42, 44, 108, 110, 112, 114, 116, 118, 120, 122, 124, 126, 128, 130) via the plurality of automated microtesters (e.g., automated microtester 10, automated microtester 102, automated microtester 104 and automated microtester 106). Through the use of automated microtester array 100, these various devices under test (e.g., devices under test 38, 40, 42, 44, 108, 110, 112, 114, 116, 118, 120, 122, 124, 126, 128, 130) may be tested all at the same time, wherein different test programs may be executed by each of the processing assemblies (e.g., processing cores 14, 16, 18, 20) at the same time. The various devices under test (e.g., devices under test 38, 40, 42, 44, 108, 110, 112, 114, 116, 118, 120, 122, 124, 126, 128, 130) may all be the same type of device or may be different types of devices. For example, devices under test 38, 40, 42, 44, 108, 110, 112, 114, 116, 118, 120, 122, 124, 126, 128, 130 may include a plurality of device types, wherein e.g., a first automated test process may be executed on the processing cores associated with the first type of device, while a second automated test process may be executed on processing cores associated with the second type of device. Through the use of automated array process 138, an administrator (not shown) of automated microtester array 100 may define and execute testing procedures/routines for the various devices under test (e.g., devices under test 38, 40, 42, 44, 108, 110, 112, 114, 116, 118, 120, 122, 124, 126, 128, 130) that are effectuated through automated microtesters 10, 102, 104 106.

The instruction sets and subroutines of automated array process 138, which may be stored on storage device 140 coupled to/included within central computing system 136, may be executed by one or more processors (not shown) and one or more memory architectures (not shown) included within central computing system 136. Examples of storage device 140 may include but is not limited to: a hard disk drive; a random access memory (RAM); a read-only memory (ROM); and all forms of flash memory storage devices.

Central computing system 136 and automated microtesters 10, 102, 104, 106 may be coupled via network 58, examples of which (as discussed above) may include but are not limited to a USB hub, an Ethernet network (e.g., a local area network or a wide area network), an intranet or the internet. As discussed above, a remote computing device (e.g., remote computing device 60) may be coupled to network 58, wherein this remote computing device (e.g., remote computing device 60) may be utilized to administer and/or control various components of automated microtester array 100. Therefore, an administrator (not shown) may use remote computing device 60 to define and/or administer various testing procedures and/or routines (e.g., automated test process 54 and our automated array process 138) of automated microtester array 100.

As discussed above, central computing system 136 (within automated microtester array 100) may execute automated array process 138 that may be configured to automate the testing of various devices under test (e.g., devices under test 38, 40, 42, 44, 108, 110, 112, 114, 116, 118, 120, 122, 124, 126, 128, 130) via the plurality of automated microtesters (e.g., automated microtester 10, automated microtester 102, automated microtester 104 and automated microtester 106). Further and as discussed above, the automated microtesters (e.g., automated microtesters, 10, 102, 104, 106) may each execute automated test process 54 that may be configured to automate the testing of various devices under test (e.g., devices under test 38, 40, 42, 44, 108, 110, 112, 114, 116, 118, 120, 122, 124, 126, 128, 130). Accordingly and through the use of automated array process 138 and the various instantiations of automated test process 54 executed on (in this example) automated microtester 10, 102, 104, 106, an administrator (not shown) of automated array process 138 and the various instantiations of automated test process 54 may define and execute testing procedures/routines for the various devices under test (e.g., devices under test 38, 40, 42, 44, 108, 110, 112, 114, 116, 118, 120, 122, 124, 126, 128, 130) that may be effectuated via e.g., automated microtesters 10, 102, 104, 106.

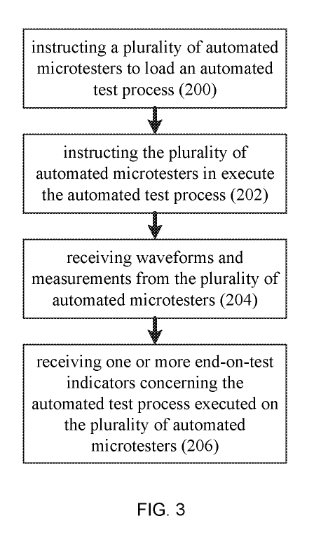

For example and referring also to FIG. 3, automated array process 138 may instruct 200 a plurality of automated microtesters (e.g., automated microtesters, 10, 102, 104, 106) to load an automated test process (e.g., automated test process 54).

As discussed above, each of the automated microtesters (e.g., automated microtesters 10, 102, 104, 106) may include an automated DUT swap system (e.g., automated DUT swap system 62) that may be configured to couple the devices that need to be tested to the automated microtesters (e.g., automated microtesters 10, 102, 104, 106). Once the testing in completed, automated DUT swap system 62 may be configured to uncouple the devices that were tested from the automated microtesters (e.g., automated microtesters 10, 102, 104, 106). Accordingly and in order to enhance efficiency, automated array process 138 may instruct 200 each of automated microtesters 10, 102, 104, 106 to load automated test process 54 while automated DUT swap system 62 is coupling the devices that need to be tested to e.g., automated microtesters 10, 102, 104, 106.

Once the devices that need to be tested are coupled to e.g., automated microtesters 10, 102, 104, 106, automated array process 138 may instruct 202 each of the plurality of automated microtesters (e.g., automated microtesters 10, 102, 104, 106) to execute the automated test process (e.g., automated test process 54).

As discussed above, automated test process 54 may be configured to automate the testing of various devices under test (e.g., devices under test 38, 40, 42, 44 coupled to automated microtester 10; devices under test 108, 110, 112, 114 coupled to automated microtester 102; devices under test 116, 118, 120, 122 coupled to automated microtester 104; and devices under test 124, 126, 128, 130 coupled to automated microtester 106).

For example and during the execution of automated test process 54, instrumentation system 46 may be configured to generate and read various signals. For example, input signals (e.g., input signal 48) may be provided to the various devices under test (e.g., devices under test 38, 40, 42, 44, 108, 110, 112, 114, 116, 118, 120, 122, 124, 126, 128, 130). Additionally, monitored signals (e.g., monitored signal 50) may be read from the various devices under test (e.g., devices under test 38, 40, 42, 44, 108, 110, 112, 114, 116, 118, 120, 122, 124, 126, 128, 130).

Accordingly and during the execution of automated test process 54, automated test process 54 may be configured to provide waveforms and measurements (e.g., waveforms and measurements 142 from automated microtester 10, waveforms and measurements 144 from automated microtester 102, waveforms and measurements 146 from automated microtester 104, waveforms and measurements 148 from automated microtester 106), which may be received 204 by automated array process 138. Examples of waveforms and measurements 142, 144, 146, 148 received 204 by automated array process 138 may include but are not limited to: the one or more input signals (e.g., input signal 48) provided to the plurality of test sites (e.g., test sites 22, 24, 26, 28) included within each of the plurality of automated microtesters (e.g., automated microtesters 10, 102, 104, 106); and the one or more monitored signals (e.g., monitored signal 50) read from the plurality of test sites (e.g., test sites 22, 24, 26, 28) included within each of the plurality of automated microtesters (e.g., automated microtesters 10, 102, 104, 106).

Once automated test process 54 has been fully executed and the testing of devices under test (e.g., devices under test 38, 40, 42, 44, 108, 110, 112, 114, 116, 118, 120, 122, 124, 126, 128, 130) has been completed, automated array process 138 may receive 306 one or more end-on-test indicators (e.g., indicator 150 from automated microtester 10, indicator 152 from automated microtester 102, indicator 154 from automated microtester 104, and indicator 156 from automated microtester 106) concerning automated test process 54 being fully executed on e.g., automated microtesters 10, 102, 104, 106, thus indicating the completion of the testing of devices under test (e.g., devices under test 38, 40, 42, 44, 108, 110, 112, 114, 116, 118, 120, 122, 124, 126, 128, 130).

Accordingly and through the use of automated DUT swap system 62, devices under test 38, 40, 42, 44, 108, 110, 112, 114, 116, 118, 120, 122, 124, 126, 128, 130 may be uncoupled from e.g., automated microtesters, 10, 102, 104, 106 and new (and untested) devices under test may be coupled to automated microtesters, 10, 102, 104, 106 so that the above-described test procedure may be repeated, wherein results of these testing procedures may be provided to a remote computing device (e.g., remote computing device 60) that may be utilized to administer and/or control automated microtester array 100. Examples of remote computing device 60 may include but are not limited to a personal computer, a notebook computer, a tablet computer and a smartphone.

### General:

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object oriented programming language such as Python, Java, Smalltalk, C++ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet.

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer/special purpose computer/other programmable data processing apparatus, such that the instructions, which execute via the processor of the computer or other programmable data processing apparatus, create means for implementing the functions/acts specified in the flowchart and/or block diagram block or blocks.

These computer program instructions may also be stored in a computer-readable memory that may direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the figures may illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. An automated microtester, for simultaneously testing a plurality of devices under test, comprising:
a processing system including a plurality of processor assemblies;
a plurality of test sites configured to releasably engage a plurality of devices under test; and
an instrumentation system that is controllable by the processing system and configured to provide one or more input signals to the plurality of test sites and read one or more monitored signals from the plurality of test sites.

2. The automated microtester of claim 1 wherein the processing system includes:
a multicore processor.

3. The automated microtester of claim 2 wherein the plurality of processor assemblies included within the processing system includes:
a plurality of processor cores included within the multicore processor.

4. The automated microtester of claim 1 wherein the plurality of test sites are configured to receive a plurality of adapter boards.

5. The automated microtester of claim 4 wherein the plurality of adapter boards are configured to releasably receive the plurality of devices under test.

6. The automated microtester of claim 4 wherein each of the plurality of adapter boards is configured to releasably receive a single device under test.

7. The automated microtester of claim 4 wherein each of the plurality of adapter boards is configured to releasably receive a plurality of devices under test.

8. The automated microtester of claim 1 wherein the processing system is configured to execute an automated test process.

9. The automated microtester of claim 8 wherein the automated test process is configured to control the instrumentation system and define the one or more input signals provided to the plurality of test sites and the one or more monitored signals read from the plurality of test sites.

10. The automated microtester of claim 8 wherein the automated test process is configured to simultaneously test each of the plurality of devices under test.

11. The automated microtester of claim 1 further comprising:
a DUT swap system configured to releasably couple the plurality of devices under test to the plurality of test sites prior to testing the devices under test.

12. The automated microtester of claim 1 wherein the DUT swap system is further configured to uncouple the plurality of devices under test from the plurality of test sites after testing the devices under test.

13. An automated microtester, for simultaneously testing a plurality of devices under test, comprising:
a processing system including a plurality of processor cores;
a plurality of test sites configured to releasably engage a plurality of devices under test; and
an instrumentation system that is controllable by the processing system and configured to provide one or more input signals to the plurality of test sites and read one or more monitored signals from the plurality of test sites.

14. The automated microtester of claim 13 wherein the processing system includes:
a multicore processor.

15. The automated microtester of claim 14 wherein the plurality of test sites are configured to receive a plurality of adapter boards.

16. The automated microtester of claim 15 wherein the plurality of adapter boards are configured to releasably receive the plurality of devices under test.

17. An automated microtester, for simultaneously testing a plurality of devices under test, comprising:
a multicore processor including a plurality of processor cores;
a plurality of test sites configured to releasably engage a plurality of devices under test; and
an instrumentation system that is controllable by the processing system and configured to provide one or more input signals to the plurality of test sites and read one or more monitored signals from the plurality of test sites;
wherein the plurality of test sites are configured to receive a plurality of adapter boards and the plurality of adapter boards are configured to releasably receive the plurality of devices under test.

18. The automated microtester of claim 17 wherein the multicore processor is configured to execute an automated test process.

19. The automated microtester of claim 18 wherein the automated test process is configured to simultaneously test each of the plurality of devices under test.
